(19) United States
(12) Patent Application Publication
(10) Pub. No.: US 2023/0411394 A1
(43) Pub. Date: Dec. 21, 2023

(54) OFFSET POWER RAIL

(71) Applicant: International Business Machines Corporation, Armonk, NY (US)

(72) Inventors: Albert M. Chu, Nashua, NH (US); Vidhi Zalani, Peekskill, NY (US); Junli Wang, Slingerlands, NY (US)

(21) Appl. No.: 17/807,877

(22) Filed: Jun. 21, 2022

(51) Int. Cl. H01L 27/118

(52) U.S. Cl. CPC H01L 27/11807; H01L 2027/11881

(57) ABSTRACT

The semiconductor device includes a first cell row, a first power rail and a second power rail. The first cell row includes a first plurality of cells. The first power rail extends from a first side of the first cell row. The first power rail connects to a first group of the first plurality of cells. The second power rail extends form a second side of the first cell row. The second power rail connects to a second group of the first plurality of cells.

### BACKGROUND

The present invention relates generally to the field of semiconductor devices, and more particularly to offset power rail design in semiconductor devices.

In semiconductor design, standard cell methodology is a method of designing integrated circuits with mostly digital-logic features. The standard cell methodology is an example of design abstraction by providing a low-level very-large-scale integration (VLSI) layout into an abstract logic representation. This allows for a designer to focus on high-level digital design aspect (i.e. logical function) of the digital design and another designer to focus on the implementation aspect. In its simplest form a standard cell is a group of transistor and interconnect structures that provide a Boolean logic function (e.g. AND, OR, XOR, XNOR, or NOT gates) or a storage function (e.g. flipflop or latch).

### SUMMARY

Embodiments of the present invention provide for a semiconductor device. In an embodiment, the semiconductor device includes a first cell row, a first power rail and a second power rail. The first cell row includes a first plurality of cells. The first power rail extends from a first side of the first cell row. The first power rail connects to a first group of the first plurality of cells. The second power rail extends form a second side of the first cell row. The second power rail connects to a second group of the first plurality of cells.

In an embodiment, the semiconductor includes a plurality of cell rows. A first power rail extends from a first side of the semiconductor device across a first cell row of the plurality of cell rows. The first power rail connects to at least one cell in the first cell row and to at least one cell in a second cell row of the plurality of cell rows.

In an embodiment, the semiconductor includes a plurality of transistors and a power rail. The power rail is connected to the plurality of transistors. A first portion of the power rail has a first length. A second portion of the power rail has a second length. The first length is greater than the second length.

### BRIEF DESCRIPTION OF THE DRAWINGS

FIG. 1 is a plan view of a portion of a standard cell semiconductor device, generally designated 100, in accordance with a first embodiment of the invention.

FIG. 2 is a plan view of a portion of a standard cell semiconductor device, generally designated 200, in accordance with a second embodiment of the invention.

FIG. 3 is a plan view of a portion of a standard cell semiconductor device, generally designated 300, in accordance with a third embodiment of the invention.

FIG. 4 is a plan view of a portion of a standard cell semiconductor device, generally designated 400, in accordance with at least one embodiment of the invention.

FIG. 5 is a plan view of a portion of a standard cell semiconductor device, generally designated 500, in accordance with at least one embodiment of the invention.

FIG. 6 is a plan view of a portion of a standard cell semiconductor device, generally designated 600, in accordance with at least one embodiment of the invention.

FIG. 7 is a plan view of a portion of a standard cell semiconductor device, generally designated 700, in accordance with at least one embodiment of the invention.

FIG. 8 is a plan view of a portion of a standard cell semiconductor device, generally designated 800, in accordance with at least one embodiment of the invention.

FIG. 9 is a plan view of a portion of a standard cell semiconductor device, generally designated 900, in accordance with at least one embodiment of the invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “an example embodiment,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface. Typically, the major surface is along a plane of a monocrystalline silicon layer on which transistor devices are fabricated.

Embodiments of the present invention recognize that conventional standard cell design utilizes a wide metal power rail at both boundaries (north and south) for power connection. For example, on the MO metal layer. Embodiments of the present invention recognize that a wide metal power rail layout limits the number of signal routing tracks that can be found on the metal layer.

Embodiments of the present invention provide for an offset power rail from cell boundaries in conventional standard cell design by utilizing narrow metal tracks. Embodiments of the present invention provide for an extended power rail that extends enough to connect all power taps, for example the standard cell power taps, without utilizing all of the space a standard power rail uses. Embodiments of the present invention provide for freeing area within standard cells or open space adjacent to standard cells for wiring tracks that may be used for signal routing. Embodiments of the present invention provide for a modified power rail design that balances electromigration/IR drop and routing tracks.

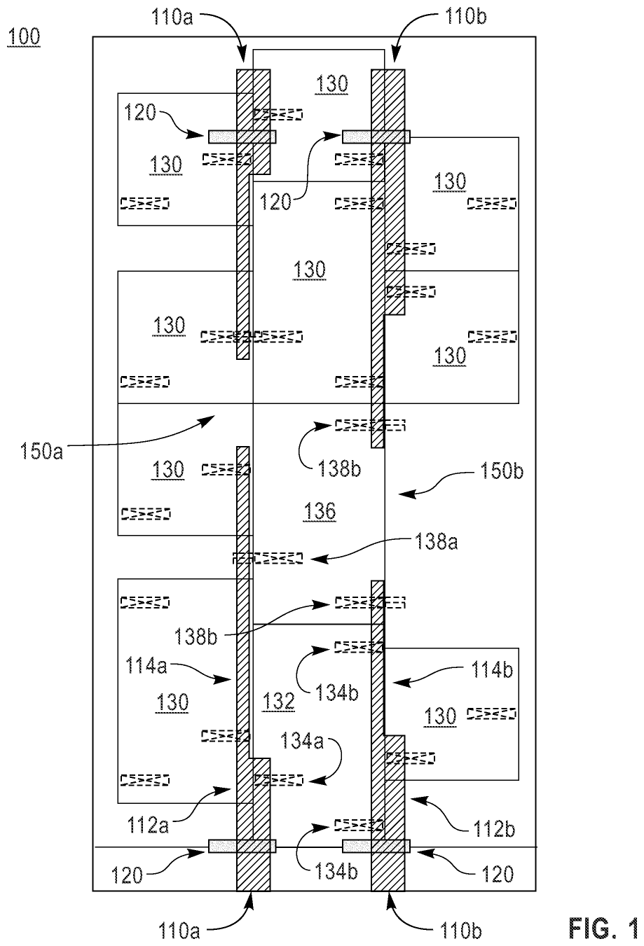

Referring now to various embodiments of the invention in more detail, FIG. 1 is a plan view of a portion of a standard cell semiconductor device, generally designated 100, in accordance with at least one embodiment of the invention. FIG. 1 provides only an illustration of one implementation and does not imply any limitation with regard to the environments in which different embodiments may be implemented. Many modifications to the depicted environment may be made by those skilled in the art without departing from the scope of the invention as recited by the claims.

The following descriptions will now relate to various methods of standard cell placements into a cell row. The methods can generally be conducted and completed by a computer or an automated system that includes among other features an internal placement engine. The internal placement engine may be embodied in hardware, software and firmware that is local to or remote from the computer or the automated system. In any case, the internal placement engine is configured to generate a placement map, which is a representation of all objects and blockages within a given design of, for example, an IC or a portion thereof. A full map can be derived from the placement map by treating all standard and non-standard cells within the design as full rectangles. A partial map can be derived from the full map by removing left or right extensions from the representative full rectangles of the full map for those cells (i.e., the non-standard cells) which have non-standard shapes, such as those described above with respect to FIGS. 1-9.

Standard cell methodology is a technique of designing ICs with a focus on the logic functions used in the IC. A standard cell includes multiple transistors that are interconnected to implement desired logic functions, such as AND, OR, NOT, XOR, and XNOR, as well as storage functions (e.g., flip-flops, latches, and buffers).

A standard cell library includes various standard cells having predetermined heights and widths. The standard cell library can include multiple standard cells for a single logic function that differ in area, speed, and power consumption. Designers can select the desired standard cells from the standard cell library based on the area, speed, and power consumption requirements of the IC and arrange the standard cells in rows and columns. Once a schematic view (a view that illustrates the terminals of the multiple transistors and the interconnections thereof) of the IC is generated by the design tool, the IC design is simulated, a layout view (a view that illustrates the actual physical implementation of the standard cells) of the IC design is generated and verified before fabrication of the IC. The cost of production of the IC is directly proportional to its layout area.

FIG. 1 is a plan view of a portion of a standard cell semiconductor device, generally designated 100, in accordance with a first embodiment of the invention. In a first embodiment, power rail 110a, b, also known as a power tap, extends from either side of the semiconductor device. As shown in FIG. 1, two power rails 110a, b exist on a first side of the semiconductor device and two power rail 110a, b exist on a second side. It should be noted, any number of power rail 110a, b may exist on either side of the semiconductor device and connect to any number of standard cells 130. As shown in FIG. 1, power rail 110a has a first width 112a and a second width 114a. In an embodiment, the first width 112a of power rail 110a provides power to standard cells 130 in the first row or the second row of standard cells and the second width 114a of power rail 110a provides power to standard cells 130 in the first row.

As shown in FIG. 1, power rail 110b has a first width 112b and a second width 114b. In an embodiment, the first width 112b of power rail 110b is above or below standard cells 130 in the second row or the third row of standard cells and the second width 114b of power rail 110b is above or below standard cells 130 in the second row. In an embodiment, as shown in FIG. 1, the second width 114a, b of power rail 110a, b may be on a first side of power rail 110a, b. For example, the second width 114a, b may provide power to the first and second rows of cells. In an alternative embodiment, the second width 114a, b of power rail 110a, b may be on a second side of power rail 110a, b. For example, the second width 114a, b, may provide power to the second and third rows of cells.

In an embodiment, power rail 110a, b provides power or ground from an upstream power delivery network via a power staple 120 to the standard cells 130 shown in FIG. 1. As shown in FIG. 1, power rails 110a provide power, in other words a supply voltage (e.g., VDD). As shown in FIG. 1, power rails 110b provide ground, in other words a ground voltage (e.g. VSS), generally 0 Volts. It should be noted, power rail 110a, b may not be on the same level of the semiconductor device 100 as the standard cells 130. In other words, power rail 110a, b may be above and/or below the standard cells 130. In an embodiment, power staple 120 may be above and/or below the standard cells 130.

As shown in FIG. 1, there are three rows of standard cells. In the first row, there are four standard cells 130, as shown by a first standard cell 130, a break between standard cell 130, a second and third standard cell 130 adjacent to each other, a break between standard cells, and a fourth standard cell 130. In the second row, there are four cells in the second, as shown by standard cell 132, standard cell 136, and two standard cells 130. In the third row, there are three standard cells, as shown by a first standard cell 130, a break between standard cells 130, and a second and third standard cell 130 adjacent to each other. It should be noted, there may be any layout or organization of standard cells in any layout or organization of standard cell rows on the semiconductor device. Additionally, it should be noted, power rails 110a are shown connected to the first and second row of standard cells and power rails 110b are shown connected to the second and third row of standard cells. However, the first row of standard cells will also have a power rail (not shown) connected to the standard cells and providing a ground voltage and the third row of standard cells will also have a power rail (not shown) connected to the standard cells and providing a supply voltage. In other words, in an embodiment there may be any number of rows of standard cells and between each row of standard cells a power rail (Power or Ground) is provided to access the standard cell rows adjacent the power rail.

It should be noted, throughout discussion, reference is made to standard cells and standard cell rows. Additionally, there may be non-standard cells (not shown) incorporated within the standard cell layout. In other words, standard cell rows may include only standard cells, only non-standard cells, or a mixture of both standard and non-standard cells. In an embodiment, non-standard cells are semiconductor devices that do not have a standard cell layout in a standard cell library due to their unique use, size, shape, etc. In an embodiment, a standard or non-standard cell may be larger than a single row and may be sized to fit in two or more adjacent rows. In other words, the cell height is as wide as two rows or more.

For simplicity, a first example standard cell 132 will now be described. Standard cell 132 is substantially similar to standard cells 130 and will now be described as standard cell 132 for simplicity in order to describe aspects of standard cell 132. However, standard cells 130 may include some or all of the aspects of standard cell 132. As shown in FIG. 1, standard cell 132 includes contact 134a connected to power rail 110a and two contacts 134b connected to power rail 110b. However, standard cell 132 may have any number of contacts 134a, b in any location within the standard cell 132. In an embodiment, as shown in FIG. 1, standard cell 132 includes contact 134a which is connected to power rail 110a. In an embodiment, contact 134a provides the power or supply voltage to standard cell 132. In an embodiment, as shown in FIG. 1, standard cell 132 includes contacts 134b which are connected to power rail 110b. In an embodiment, contacts 134b provide the ground or ground voltage to standard cell 132. As noted above, power rails 110a, b may be above and/or below the standard cells 132, therefore, contacts 134a, b may be electrically connected to standard cell 132 using any process known in the art, such as a via (not shown). As shown in FIG. 1, the contacts 134a, b of standard cell 132 are found within the boundaries of standard cell 132 and power rail 110a, b is within the boundaries of standard cell 132. As discussed in the above paragraph, a non-standard cell may have some or all of the characteristics of a standard cell.

For simplicity, a second example standard cell 136 will now be described. Standard cell 136 is substantially similar to standard cells 130 and will now be described as standard cell 136 for simplicity in order to describe aspects of standard cell 136. However, standard cells 130 may include some or all of the aspects of standard cell 136. As shown in FIG. 1, standard cell 136 includes contact 138a connected to power rail 110a and two contacts 138b connected to power rail 110b. However, standard cell 136 may have any number of contacts 138a, b in any location within the standard cell 136. In an embodiment, as shown in FIG. 1, standard cell 136 includes contact 138a which is connected to power rail 110a. In an embodiment, contact 138a provides the power or supply voltage to the standard cell 136. As shown in FIG. 1, contact 138a extends outside of the cell boundary of standard cell 136 and into a space between standard cells 130 that is not occupied by any standard cells 130. In an embodiment, this allows contact 138a to be above or below power rail 110a. In an embodiment, as shown in FIG. 1, standard cell 136 includes contacts 138b which are connected to power rail 110b. In an embodiment, contacts 138b provide the ground or ground voltage to standard cell 138. In an embodiment, contact 138b may extend into the unoccupied space of an adjacent row or extend to a contact (not shown) of a standard cell in an adjacent row, where the power or ground contacts of the adjacent cells are aligned. As noted above, power rails 110a, b may be above and/or below the standard cells 136, therefore, contacts 138a, b may be electrically connected to standard cell 136 using any process known in the art, such as a via (not shown). As shown in FIG. 1, the contacts 138a, b of standard cell 136 extend outside the boundaries of standard cell 136 and power rail 110a is outside the boundaries of standard cell 136 while power rail 110b is within the boundaries of standard cell 136.

As shown in FIG. 1, unused space 150a is found between power rail 110a extending from both sides of semiconductor device 100 and unused space 150b is found between power rail 110b extending from both sides of semiconductor device 100. In an embodiment, unused space 150a, b may be used to free up wiring tracks for signal routing, etc. In FIG. 1, power rail 110a, for example, extends from power tap 120 in a first direction. In other words, power rail 110a extends, in general, from power tap 120 towards the opposite end of the first row of standard cells and power rail 110a provides power or ground to cells in the first row on a first side of power tap 120. In an embodiment, power rail 110a may extend from one or both directions of power tap 120. For simplicity, standard cells 130 are only shown on one side of power tap 120 in the first, second and third row of cells. Alternatively, standard cells 130 may be on the opposite on both sides of power tap 120 and power rail 110a may extend in both directions from power tap 120. In other words, power rail 110a may provide power or ground to cells in the first row or second row that are on either side of power tap 120.

In an embodiment, while two segments of power rail are shown in each row in FIGS. 1, there may be any number of power rail segments that provide power or ground to any number of cells on one side, both sides or either side of power tap 120. Additionally, the power rail segments may be in any configuration. In other words, a first power rail segment in a first cell row may extend in a first direction from a power tap and a second power rail segment in the same first cell row may extend in an opposite direction from the first direction from the same power tap and/or a different power tap. Even further, a power rail segment in the first cell row may also extend in the first direction and the opposite direction from the first direction from a same power top and/or different power tap.

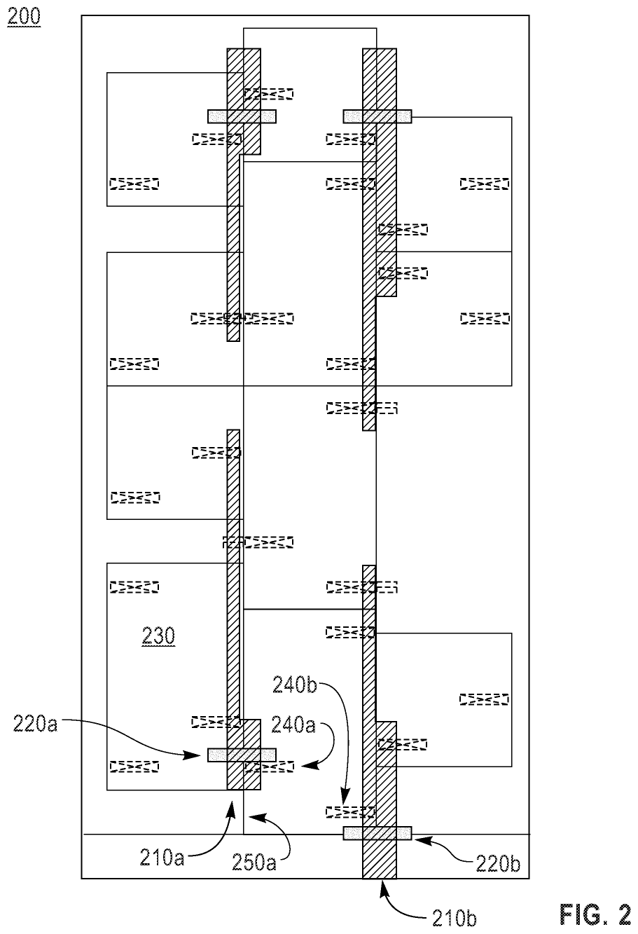

FIG. 2 is a plan view of a portion of a standard cell semiconductor device, generally designated 200, in accordance with a second embodiment of the invention. In a second embodiment, standard cell semiconductor device 200 is substantially similar to standard cell semiconductor device 100. In the second embodiment, standard cell semiconductor device 200 includes similar features to standard cell semiconductor device 100. As noted above, in the second embodiment, standard cell semiconductor device 200 includes two power rail 210a, b that exist on a first side of the standard cell semiconductor device 200. In the second embodiment, power rail 210a extends to the end of standard cell 230. In the second embodiment, power staple 220a connected to power rail 210a is not in line with power staple 220b connected to power rail 210b. Here, power staple 220a only needs to extend to a first length to provide power to contact 240a in the second row of standard cells and power staple 220b extends to a second length to provide ground to contact 240b in the second row of standard cells. In the second embodiment, unused space 250a may be used to free up wiring tracks for signal routing, etc.

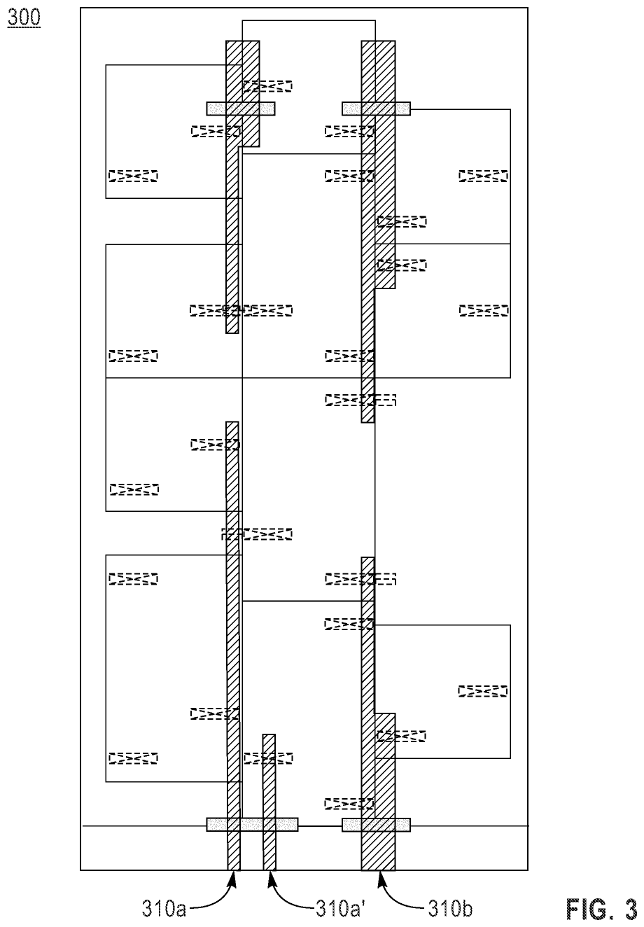

FIG. 3 is a plan view of a portion of a standard cell semiconductor device, generally designated 300, in accordance with a third embodiment of the invention. In a third embodiment, standard cell semiconductor device 300 is substantially similar to standard cell semiconductor device 100 and standard cell semiconductor device 200. In the third embodiment, standard cell semiconductor device 300 includes similar features to standard cell semiconductor device 100 and standard cell semiconductor device 200. In the third embodiment, standard cell semiconductor device 300 includes power rail 310a, a′, b that exist on a first side of the standard cell semiconductor device 300. In the third embodiment, power rail 310a provides power to the first row of standard cells, power rail 310a′ provides power to the second row of standard cells, and power rail 310b provides ground to the second and third rows of standard cells.

It should be noted, FIGS. 1-3 provide three embodiments of the invention. During standard cell placement and standard cell row design, a semiconductor device may incorporate any, some, or all of the three embodiments in the design and placement of the standard cells.

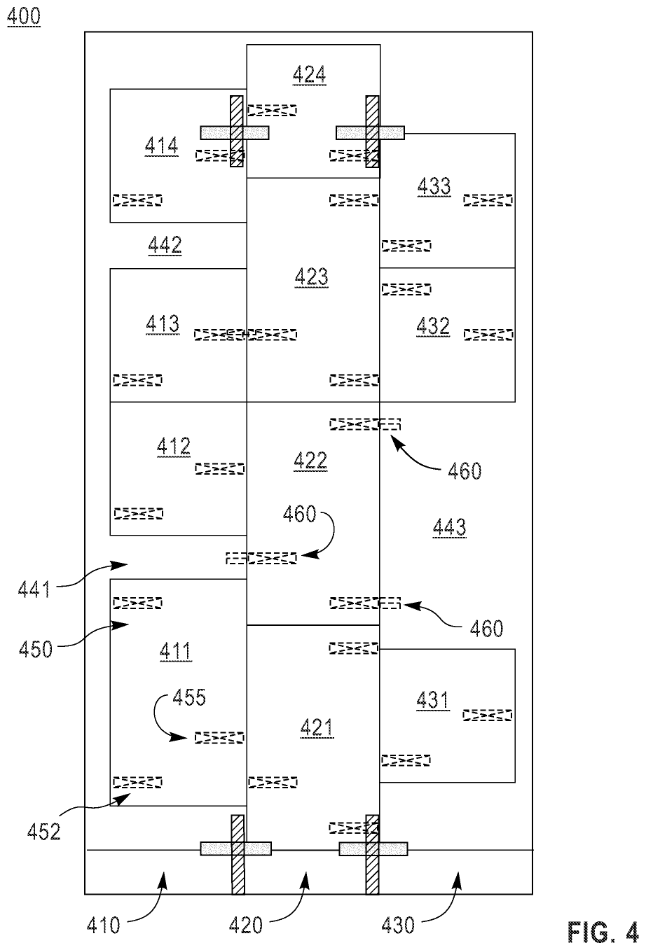

FIG. 4 through FIG. 9 are a process for creating elements of the first embodiment, second embodiment, and third embodiment of the invention discussed above.

FIG. 4 is a plan view of a portion of a standard cell semiconductor device, generally designated 400, in accordance with at least one embodiment of the invention. In FIG. 4, standard cells have been laid out in three rows. In an embodiment, “open space” is area on the semiconductor device 400 that does not have a standard cell placed and the open space is available for other uses. In the first row 410, four standards cells and two open spaces exists. Here, the first row consists of a standard cell 411, an open space 441, a standard cell 412, a standard cell 413, an open space 442, and a standard cell 414. In the second row 420, four standard cells exist. Here, the second row consists of standard cell 421, standard cell 422, standard cell 423, and standard cell 424. In the third row 430, three standard cells and an open space exist. Here, the third row consists of standard cell 431, open space 443, standard cell 432, and standard cell 433. It should be noted, there may be any number of rows of standard cells and the standard cells may be laid out in any order including any number of open spaces.

Each standard cell shown in FIG. 4 includes a plurality of contacts. For simplicity, the contacts will be described with reference solely to standard cell 411. However, each standard cell may have any number of contacts, as described and referenced in the discussions of FIGS. 1-3. In standard cell 411, three contacts exist, contact 450, contact 452, and 455. In standard cell 411, contact 450 and contact 452 will receive ground and contact 455 will receive power, as discussed above. It should be noted, standard cells in first row 410 have power contacts adjacent to second row 420 and ground contacts on the opposite side of the first row 410. In other words, standard cells in the same row will have all power contacts on one side of the row and all ground contacts on the other side of the row. Adjacent rows will have contacts that receive power on a side that is adjacent to a row that has power contacts on the same side and contacts that receive ground on a side that is adjacent to a row that has ground contacts on the same side. For example, the first row 410 and the second row 420 will have adjacent contacts that receive power and the second row 420 and third row 430 will have adjacent contacts that receive ground.

In an embodiment, upon placement of standard cells in the first row 410, second row 420, and third row 430, it is determined if contacts exist that have open spaces in an adjacent row across from the contact. In this instance, the contacts are extended, as shown by extended contacts 460. Here, standard cell 422 has a first contact adjacent to the first row 410, and that contact is then extended within the open space 441 of the first row 410. Additionally, standard cell 422 has two contacts that are adjacent the third row 430, and those contacts are then extended within the open space 443 of the third row 430.

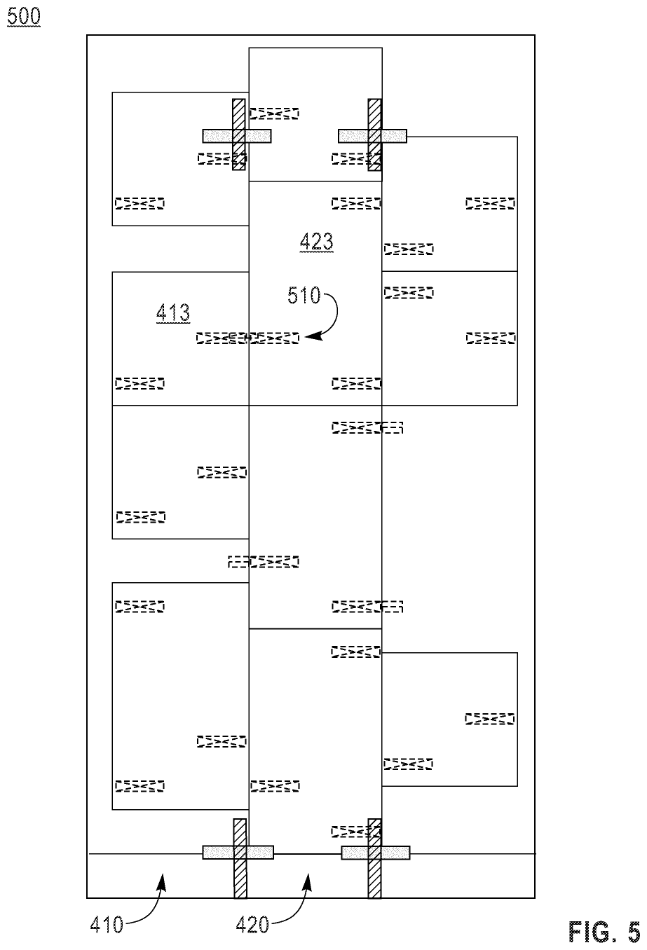

FIG. 5 is a plan view of a portion of a standard cell semiconductor device, generally designated 500, in accordance with at least one embodiment of the invention. In FIG. 5, standard cells have already been laid out in three rows, as discussed above in reference to FIG. 4. As shown in FIG. 5, standard cell 413 and standard cell 423 have contacts that are adjacent to each other. As discussed above, both the contact in standard cell 413 and the contact in standard cell 423 are to receive power. Here, the adjacent contact of standard cell 413 and standard cell 423 are merged to form a merged contact 510. It should be noted, this merged contact can be formed for two adjacent contacts that are power contacts or for two adjacent contacts that are ground contacts of their respective standard cells.

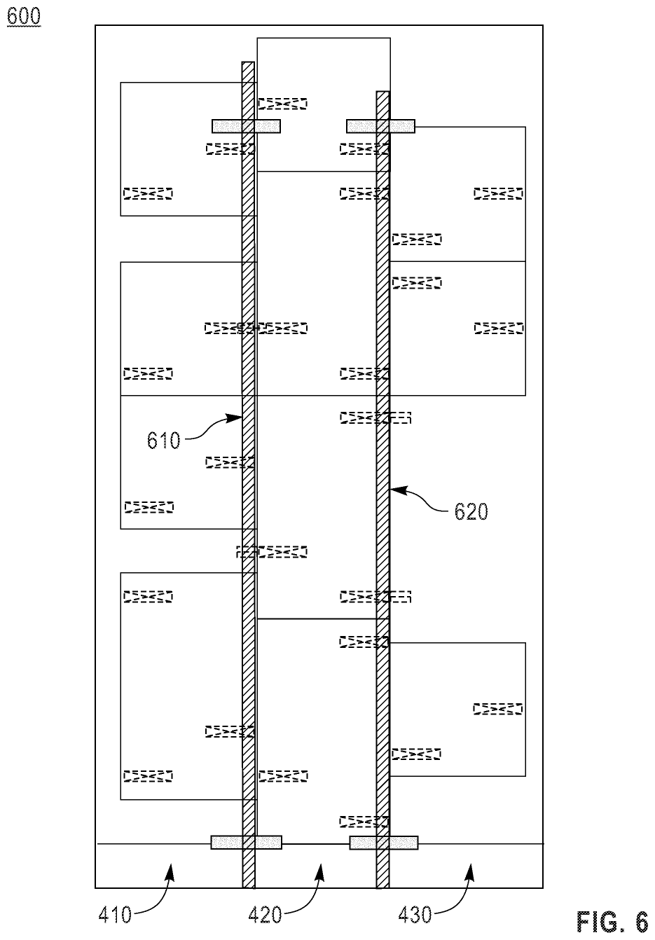

FIG. 6 is a plan view of a portion of a standard cell semiconductor device, generally designated 600, in accordance with at least one embodiment of the invention. In an embodiment, a power rail is determined to be placed between adjacent rows. It should be noted, power rail may provide power or ground to the standard cells in the adjacent rows. In an embodiment, the location of the power rail is determined based on the number of contacts of the standard cells that the power rail will be in contact with within the row. In other words, the power rail will be placed in a first row over a second row if the power rail can be in contact with more contacts of the first row than contacts of the second row.

In FIG. 6, power rail 610 has been placed in the first row 410 for providing power to standard cells of the first row 410 and second row 420. As shown in FIG. 6, by placing the power rail 610 in the first row 410, power rail 610 can provide power to all four of the standard cells in the first row 410 and two of the standard cells in the second row 420, via the shared contact and extended contact discussed above, for a total of six contacts. However, if the power rail 610 had been placed in the second row 420 (not shown), the power rail 610 would provide power to all four of the standard cells in the second row 420 and one of the standard cells in the first row 410 via the shared contact discussed above, for a total of five contacts. Thus, the power rail 610 is placed in the first row 410.

In FIG. 6, power rail 620 has been placed in the second row for providing ground to standard cells of the second row 420 and third row 430. As shown in FIG. 6, by placing power rail 620 in the second row 420, power rail 620 can provide ground to all four standard cells in the second row 420 and none of the standard cells found in the third row 430, for a total of seven contacts. However, if the power rail 620 has been placed in the third row 430 (not shown), the power rail 620 would provide ground to all three standard cells in the third row 430 and one of the standard cells in the second row 420 via the extended contact discussed above, for a total of five contacts. Thus, the power rail 620 is placed in the second row 420.

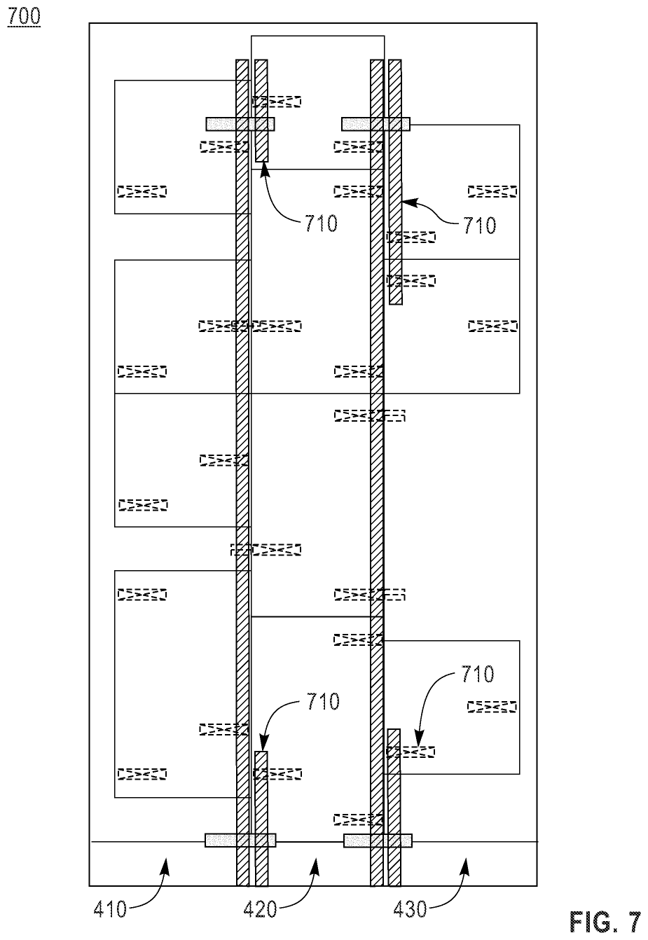

FIG. 7 is a plan view of a portion of a standard cell semiconductor device, generally designated 700, in accordance with at least one embodiment of the invention. In an embodiment, partial power rails 710 are added to route to the remaining contacts. As discussed above, power rail may provide power or ground to the standard cells in the adjacent rows. Here, a partial power rail 710 is added to either end of the second row 420 of standard cells in order to provide power to contacts of standard cells that have not had power provided to contacts of the standard cells in the second row 420. Additionally, a power rail 710 is added to either end of the third row 430 of standard cells in order to provide ground to contacts of standard cells that have not had power provided to contacts of the standard cells in the third row 430.

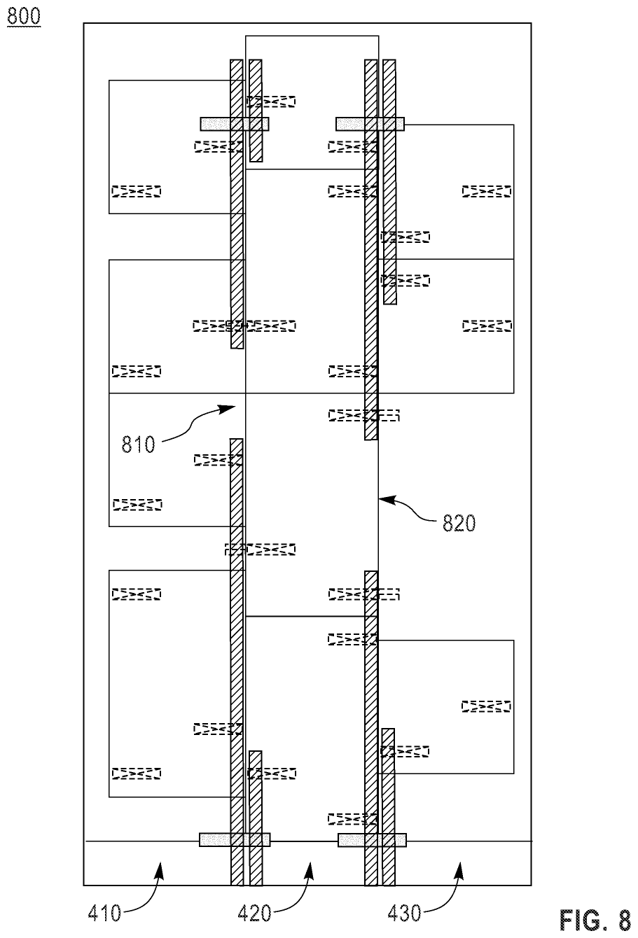

FIG. 8 is a plan view of a portion of a standard cell semiconductor device, generally designated 800, in accordance with at least one embodiment of the invention. In an embodiment, the power rail in the first row 410 has been split creating an open space 810. Here, the power rail still receives power from the power staple at either end of the first row 410. In an embodiment, the power in the second row 420 has been split creating an open space 820. Here, the power rail still receives ground from the power staple at either end of the second row 420. It should be noted, power rails may be split to create open space 810 and/or open space 820 based on design rules for standard cell placement.

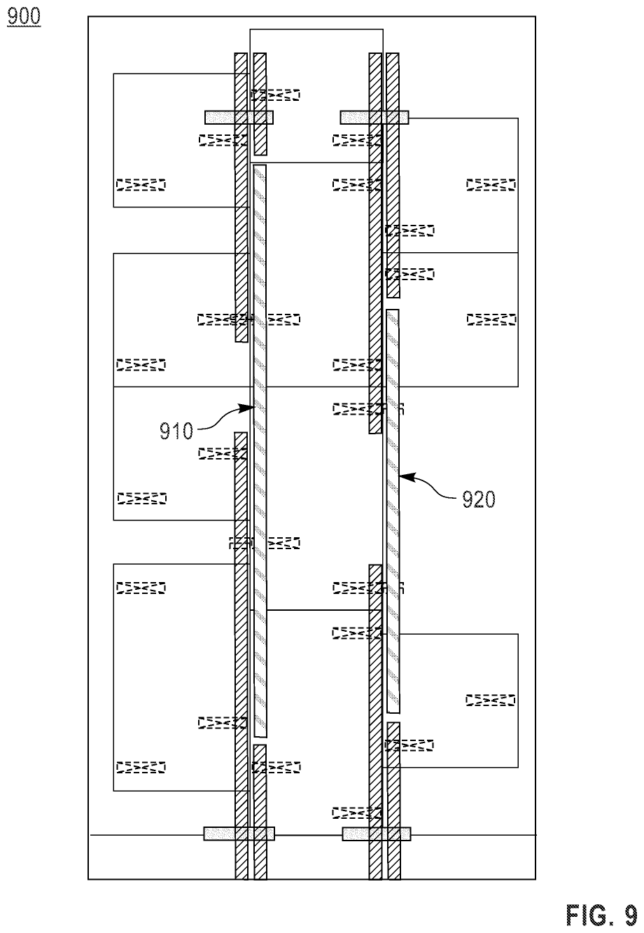

FIG. 9 is a plan view of a portion of a standard cell semiconductor device, generally designated 900, in accordance with at least one embodiment of the invention. In an embodiment, the open space 810 and open space 820, discussed above, may now be used for other purposes. In an embodiment, area 910 and area 920 are now used for signal routing. In alternative embodiments, if routing resources are not needed, area 910 and area 920 may be used to maximize routing tracks for power/ground. In yet another alternative embodiment, area 910 and area 920 may be used to help IR drop. In general, space 810, 820, 910, and 920 are not needed for power distribution so they can be used for either signal routing, leave it empty, or use it for power or ground connection to help IR drop.

Upon optimization of power rails as discussed in reference to FIG. 4 through FIG. 9 elements of the first embodiment, second embodiment, and third embodiment of the invention discussed above may be implemented.

The integrated circuit chips resulting from the processes described herein can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein

1. A semiconductor device comprising:
a first cell row, wherein in the first cell row includes a first plurality of cells;
a first power rail extending from a first side of the first cell row, wherein the first power rail connects to a first group of the first plurality of cells; and
a second power rail extending from a second side of the first cell row, wherein the second power rail connects to a second group of the first plurality of cells.

2. The semiconductor device of claim 1, further comprising:
an open space between the first power rail and the second power rail, wherein the open space is used for signal routing.

3. The semiconductor device of claim 1, wherein the first plurality of cells are standard cells.

4. The semiconductor device of claim 1, wherein the first plurality of cells are standard cells and non-standard cells.

5. The semiconductor device of claim 1, further comprising:
a second cell row adjacent to the first cell row, wherein in the second cell row includes a second plurality of cells, and wherein a first group of the second plurality of cells connects to the first power rail.

6. The semiconductor device of claim 5, wherein the first group of the second plurality of cells has contacts that extend from the second cell row to the first cell row and connect to the first power rail.

7. The semiconductor device of claim 5, further comprising:
a third power rail extending from a first side of the second cell row, wherein the third power rail connects to a second group of the second plurality of cells.

8. The semiconductor device of claim 5, further comprising:
A fourth power rail extending from a second side of the second cell row, wherein the fourth power rail connects to a third group of the second plurality of cells.

9. A semiconductor device comprising:
a plurality of cell rows;
a first power rail extending from a first side of the semiconductor device across a first cell row of the plurality of cell rows; and
wherein the first power rail connects to at least one cell in the first cell row and to at least one cell in a second cell row of the plurality of cell rows.

10. The semiconductor device of claim 9, further comprising:
a second power rail extending from a first side of the semiconductor device across the second cell row of the plurality of cell rows; and
wherein the second power rail connects to at least one cell in the second cell row of the plurality of cell rows.

11. The semiconductor device of claim 10, wherein the first power rail has a first length from the first side and wherein the second power rail has a second length from the first side, and wherein the first length is larger than the second length.

12. The semiconductor device of claim 10, wherein the first power rail and the second power rail are connected to form a single power rail.

13. The semiconductor device of claim 10, wherein an open space is between the first power rail and the second power rail.

14. The semiconductor device of claim 9, wherein each cell row of the plurality of cell rows includes a plurality of cells and wherein the plurality of cells are selected from the group consisting of standard cells and non-standard cells.

15. The semiconductor device of claim 10, further comprising:
a power tap connected to the first power rail and the second power rail, wherein the power tap is inside a first standard cell in the first cell row and wherein the first standard cell is on the first side of the semiconductor device.

16. The semiconductor device of claim 10, further comprising:
a power tap connected to the first power rail and the second power rail, wherein the power tap is between a first standard cell in the first cell row and the first side of the semiconductor device.

17. A semiconductor device comprising:
a plurality of transistors; and
a power rail connected to the plurality of transistors, wherein a first portion of the power rail has a first length, and a second portion of the power rail has a second length, and wherein the first length is greater than the second length.

18. The semiconductor device of claim 17, wherein the plurality of transistors form a plurality of cells and wherein the plurality of cells form a plurality of cell rows.

19. The semiconductor device of claim 18, where the plurality of cells are selected from the group consisting of standard cells and non-standard cells.

20. The semiconductor device of claim 17, wherein the first portion of the power rail and the second portion of the power rail are connected.
